(19) United States
(12) Patent Application Publication
(10) Pub. No.: US 2015/0162475 A1
(43) Pub. Date: Jun. 11, 2015

(54) SOLAR CELL MODULE AND METHOD OF MANUFACTURING THE SAME

(71) Applicants: Koo Lee, Daejeon (KR); Chang Seon Hwang, Daejeon (KR); Byung Man Kim, Daejeon (KR); Woo Jin Kim, Daejeon (KR); Yong Hyun Cho, Daejeon (KR); Il Kyo Lee, Daejeon (KR); Ki Han Ko, Daejeon (KR); Seol Hui Jung, Daejeon (KR)

(72) Inventors: Koo Lee, Daejeon (KR); Chang Seon Hwang, Daejeon (KR); Byung Man Kim, Daejeon (KR); Woo Jin Kim, Daejeon (KR); Yong Hyun Cho, Daejeon (KR); Il Kyo Lee, Daejeon (KR); Ki Han Ko, Daejeon (KR); Seol Hui Jung, Daejeon (KR)

(73) Assignee: S-ENERGY CO., LTD., Seongnam-si, Gyeonggi-do (KR)

(21) Appl. No.: 14/404,636

(22) PCT Filed: Aug. 31, 2012
(86) PCT No.: PCT/KR2012/006970

§ 371 Date: Dec. 1, 2014

(30) Foreign Application Priority Data
May 30, 2012 (KR) 10-2012-0057791
Aug. 31, 2012 (KR) 10-2012-0096054

(51) Int. Cl. H01L 31/056; H01L 31/0203

(52) U.S. Cl. CPC H01L 31/056; H01L 31/0203

(57) ABSTRACT

The present invention relates to a solar cell module comprising: a transparent plate; a support plate positioned to face the transparent plate; at least one unit cell disposed between the transparent plate and the support plate; a first filler disposed between the transparent plate and the unit cell; a second filler disposed between the support plate and the unit cell; and a reflective layer which is disposed between the second filler and the support plate, and which reflects sunlight that has passed through the transparent plate on the unit cell, wherein the length of the reflective layer is shorter than the length of the second filler and the second filler directly comes in contact with the support plate. According to this configuration, the amount of sunlight irradiated on the unit cell can be increased, thereby enhancing generating efficiency and improving the durability of the solar cell module.

### CROSS REFERENCE TO PRIOR APPLICATIONS

This application is a National Stage Application of PCT International Patent Application No. PCT/KR2012/005568 filed on Jul. 13, 2012, under 35 U.S.C. §371, which claims priority to Korean Patent Application No. 10-2012-0025072 filed on Mar. 12, 2012, which are all hereby incorporated by reference in their entirety.

### BACKGROUND

The present invention relates to a solar cell module and a method of manufacturing the same.

A solar cell module is a semiconductor element which converts light energy into electrical energy using photoelectric effect, and comes into spotlight because of non-polluting, no-noise, and inexhaustible supply energy. Recently, the solar cell module spreads around the globe due to high awareness on environmental issues. Interest in global warming due to emission of CO₂ picks up and demand on clean energy grows strong. A solar cell is expected to become a clean energy source due to safety and ease of handling.

A solar cell module includes a plurality of unit cells connected to each other with a gap therebetween and a transparent plate and an insulator positioned at both sides of the unit cells.

The electrical energy is generated by supplying sunlight passing through the transparent plate of the solar cell module to the unit cells. Since the solar cell module generates the electrical energy by using the sunlight directly radiated to each unit cell, the number of the unit cells should be increased in order to increase electricity generation capacity of the solar cell module. However, this method has problems such that a size of the solar cell module becomes large proportional to the number of the unit cells.

To solve such problems, the applicant has suggested a solar cell module having improved electricity generation efficiency compared to the solar cell module having the same size by disposing a reflective layer in solar cell module and supplying to each unit cell the sunlight that is not directly radiated to each unit cell. This technique is filed in Korean Patent Office as Patent Application No. 2010-0111814 and is granted on Oct. 21, 2011.

### SUMMARY OF THE INVENTION

The present invention has been made in an effort to provide a solar cell module and method of manufacturing the same having advantages of obtaining higher electricity generation efficiency than a conventional solar cell module having the same size and improving durability.

A solar cell module according to an exemplary embodiment of the present invention includes a transparent plate, a support plate positioned to face the transparent plate, at least one unit cell disposed between the transparent plate and the support plate, a first filler disposed between the transparent plate and the unit cell, a second filler disposed between the support plate and the unit cell, and a reflective layer disposed between the second filler and the support plate, wherein a length of the reflective layer is shorter than that of the second filler and the second filler is directly attached with the support plate.

The reflective layer can reflect solar light passing through the transparent plate to the unit cell or reflect solar light passing through the support plate to the exterior.

The plurality of unit cells may be disposed apart from each other, the reflective layer may include a plurality of reflective members, the plurality of reflective members may be disposed apart from each other, and each reflective member may be disposed to face a space between neighboring two of the unit cells. A surface region of the reflective layer facing the unit cells is flat, and a surface region of the reflective layer facing the space between the neighboring two of the unit cells includes a curved surface being convex upwardly.

The second filler may penetrate through a space between the plurality of reflective members and may be directly attached to the support plate.

The solar cell module may further include a cover covering sides of the transparent plate and the support plate and made of synthetic resin.

The cover may be made of resin selected from the group consisting of polyamide, polystyrene, acryl, and polyethylene and combinations thereof.

The solar cell module may further include a metal frame mounted at the cover, wherein protrusions and depressions are formed on contacting surfaces of the cover and the frame, and the contacting surfaces of the cover and the frame are coupled to each other by coupling the depressions of the cover to the protrusions of the frame. The solar cell module may further include a supporter connected to a surface of the support plate opposite to a surface of the support plate facing the reflective layer, and the supporter may include first and second regions attached on the support plate and a third region formed between the first region and the second region and apart from the support plate.

The solar cell module may further include a junction box mounted at an opposite surface of a surface facing the unit cell among surfaces of the support plate and a bus bar having a side connected to the unit cell and the other side connected to the junction box, wherein a hole is bored at the support plate, the junction box is mounted at a position corresponding to the hole, and the bus bar penetrates through the hole and is connected to the junction box.

The reflective layer may include a first reflective surface facing the transparent plate and a second reflective surface facing the support plate, and the support plate may be transparent.

The solar cell module may further include an insulating layer formed on the first reflective surface and being transparent.

A solar cell module according to another exemplary embodiment of the present invention includes a transparent plate, a support plate connected to the transparent plate in a state of facing the transparent plate, at least one unit cell disposed between the transparent plate and the support plate, a junction box mounted at an exterior surface of the support plate, and a bus bar having a side connected to the unit cell and the other side connected to the junction box, wherein a hole is bored at the support plate, the junction box is mounted at a position corresponding to the hole, and the bus bar penetrates through the hole and connected to the junction box.

The transparent plate and the support plate may be made of glass.

A solar cell module according to another exemplary embodiment of the present invention includes a transparent plate, a support plate positioned to face the transparent plate, at least one unit cell disposed between the transparent plate and the support plate, a first filler disposed between the transparent plate and the unit cell, a second filler disposed between the support plate and the unit cell, and a supporter attached just on a surface of the support plate.

The supporter may include first and second regions attached on the support plate and a third region formed between the first region and the second region and apart from the support plate.

The transparent plate and the support plate are attached by the first filler and the second filler, and no frame is mounted at edges of the transparent plate and the support plate.

A method of manufacturing a solar cell module according to another exemplary embodiment of the present invention includes disposing a plurality of unit cells between a transparent plate and a support plate facing each other, disposing a first filler between the transparent plate and the unit cell, disposing a second filler between the support plate and the unit cell, disposing a reflective layer having plane area smaller than that of the second filler between the second filler and the support plate, wherein solar light is reflected on at least one surface of a surface facing the transparent plate and a surface facing the support plate, and directly attaching the second filler and the support plate by heating the second filler.

The method may further include coupling a cover made of synthetic resin to side surfaces of the transparent plate and the support plate.

The method may further include forming first protrusions and depressions on an exterior surface of the cover, manufacturing a metal frame having second protrusions and depressions corresponding to the first protrusions and depressions formed thereon, and mounting the metal frame on the cover by coupling the second protrusions and depressions with the first protrusions and depressions.

The method may further include boring a hole at the support plate, mounting a junction box at the support plate, and connecting a bus bar connected to the unit cell to the junction box by drawing out the bus bar through the hole, wherein the junction box covers the hole.

Since solar light radiated between unit cells is reflected by a reflective layer and then is supplied to the unit cells again so as to be used as electricity generation energy according to an exemplary embodiment of the present invention, a solar cell module having the same size as a conventional one may achieve high electricity generation efficiency. In addition, since a second filler and a support plate made of glass are directly attached, adhesive property may be excellent and durability of a solar cell module may be improved.

Since a cover made of synthetic resin acts as a buffer according to an exemplary embodiment of the present invention, risk of damaging a transparent plate and a support plate by external impact may be minimized.

Since a metal frame is attached by coupling protrusions and depressions of the cover the metal frame according to an exemplary embodiment of the present invention, manufacturing time of the solar cell module may be reduced and thereby improving productivity.

Since the solar light passing through the support plate is reflected by a second reflective surface and is out according to an exemplary embodiment of the present invention, cycle-life deterioration of the solar cell due to rise of interior temperature may be prevented.

Since an entire surface of a case part is flat according to an exemplary embodiment of the present invention, foreign materials such as dust and snow may be easily removed from a surface of a transparent plate. Therefore, the transparent plate may maintain cleanliness for a long time, cleaning of the transparent plate may be easy, and electricity generation efficiency of the solar cell module may be enhanced. Since the cover and the frame is not mounted at the case part, manufacturing may be easy and weight is light.

Even though a support plate is slightly curved due to a shape of a supporter, the supporter can be closely contacted to the support plate and durability may be improved according to an exemplary embodiment of the present invention.

### BRIEF DESCRIPTION OF THE DRAWINGS

FIG. 1 is a cross-sectional view of a solar cell module according to an exemplary embodiment of the present invention,

FIG. 2 is an exploded perspective view of a solar cell module illustrated in FIG. 1,

FIG. 3 to FIG. 8 are cross-sectional views of a solar cell module according to another exemplary embodiment of the present invention,

FIG. 9 illustrates a glass plate, and a cover and a frame that is not coupled to a side of the glass plate,

FIG. 10 is an enlarged view of X in FIG. 9,

FIG. 11 illustrates a support plate and a junction box that are separated from each other,

FIG. 12 illustrates a support plate and a junction box in FIG. 11 that are coupled to each other,

FIG. 13 is a cross-sectional view of a solar cell module according to another exemplary embodiment of the present invention,

FIG. 14 is an enlarged view of Y illustrated in FIG. 13,

FIG. 15 is a perspective view of a solar cell module according to another exemplary embodiment of the present invention,

FIG. 16 is an enlarged view of a supporter illustrated in FIG. 15, and

FIG. 17 is a perspective view of a solar cell module according to another exemplary embodiment of the present invention.

### DETAILED DESCRIPTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention. Like reference numerals designate like elements throughout the specification.

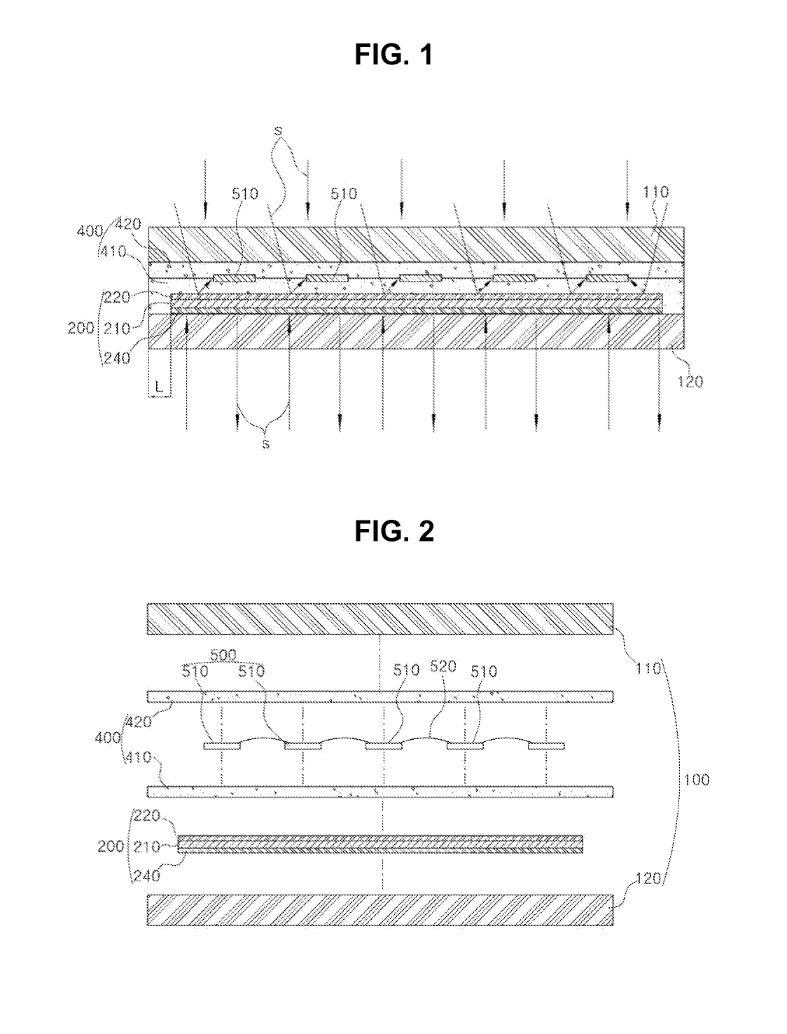

FIG. 1 and FIG. 2 illustrate an exemplary embodiment of the present invention, and a solar cell module according to the present exemplary embodiment includes a case part 100, a reflective layer 200, a filler layer 400 and a solar cell 500.

The case part 100 transmits solar light and functions as a case of the solar cell 500, and includes a transparent plate 110 and a support plate 120.

The transparent plate 110 concentrates the solar light required for generating electricity and protects a solar cell. The transparent plate 110 may be made of glass.

Since the transparent plate 110 is exposed to the outside, tempered glass may be used as the transparent plate 110 to prevent breakage. Other than glass, any material that is transparent and has sufficient strength may be used as the transparent plate 110. In addition, the transparent plate 110 may have a quadrangular shape as illustrated in the drawings, a circular shape, or any other shape according to mounting environment.

If necessary, an additional protective film, not illustrated in the drawings, may be attached on a surface of the transparent plate 110 so as to block ultraviolet rays having bad influence on cycle-life of the solar cell and prevent surface damage of the transparent plate 110 from the outside.

The support plate 120 included in the case part 100 with the transparent plate 110 functions as protection of the solar cell and a mounting plate when the solar cell module is mounted. The support plate 120 has the same area and shape as the transparent plate 110, and is made of glass similar to the transparent plate 110, TPT (Tedlar/PET/Tedlar), PET (PolyEthylene Terephthalate), etc.

The support plate 120 and the transparent plate 110 are disposed to face each other.

The reflective layer 200 is mounted in the case part 100.

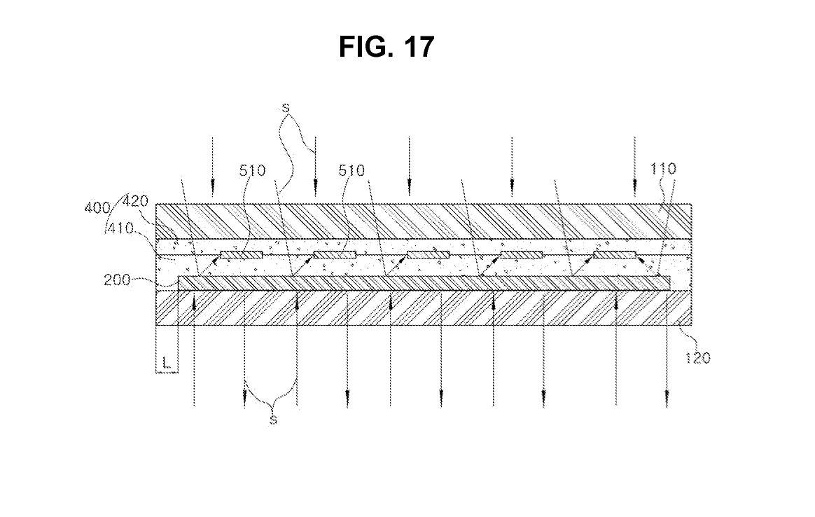

The reflective layer 200 reflects solar light that passes through the transparent plate 110 and is not radiated directly to each unit cell 510 of the solar cell 500 but is radiated to a space between the unit cells 510 so as to help the unit cells utilize the solar cell as energy source. The reflective layer 200 includes a body 210 and first and second reflective surfaces 220 and 240. However, the reflective layer 200 may include any one of the first reflective surface 220 and the second reflective surface 240 or may not include the body 210. In this case, the reflective layer 200, as shown in FIG. 17, may be formed as one layer, and both surfaces of the reflective layer 200 may be used as reflective surfaces.

The reflective layer 200, in cross-sectional view, is shorter than the transparent plate 110 and the support plate 120. A length L from an edge of the transparent plate 110 or an edge of the support plate 120 to an edge of the reflective layer 200 may be 10 to 15 mm. Adherence of the filler layer 400 and the support plate 120 may be deteriorated if the length L is smaller than 10 mm. If the length L is larger than 15 mm, electricity generation efficiency may be deteriorated because a space in which the solar cell 500 is disposed is reduced.

The body 210 functions as a frame for forming the first and second reflective surfaces 220 and 240. The body 210 has a plate shape and is mounted on a surface of the support plate 120 facing the transparent plate 110.

In addition, the first reflective surface 220 guides the solar light passing through the transparent plate 110 to the solar cell 500, made of reflective material that can reflect the solar light, and is formed on a surface of the body 210 facing the transparent plate 110.

Aluminum, silver, mercury, platinum, titanium or silver foil that can reflect light may be used as the first reflective surface 220. The first reflective surface 220 may be formed by mirror coating or deposition method for manufacturing a mirror.

In addition, the second reflective surface 240 reflects light passing through the support plate 120 and maintains appropriate temperature in a space between the transparent plate 110 and the support plate 120. The second reflective surface 240 is formed on a surface of the body 210 facing the support plate 120 using the same material as or similar material to the first reflective surface 220.

The second reflective surface 240 is formed by the same method as or similar method to the first reflective surface 220.

In a state that the reflective layer 200 is provided, the filler layer 400 is formed between the transparent plate 110 and the support plate 120.

The filler layer 400 fixes and protects the solar cell 500 and connects the transparent plate 110 and the support plate 120. The filler layer 400 is made of ethylene vinyl acetate (EVA), polyvinylbutyral (PVB) of film shape, ionomer, or silicon-based sheet.

At this time, the filler layer 400 includes a first filler 410 and a second filler 420. The first filler 410 is transparent and has insulating nature. The first filler 410 is laid on a surface of the reflective layer 200 facing the transparent plate 110. The second filler 420 is transparent and has insulating nature. The second filler 420 is laid on a surface of the transparent plate 110 facing the reflective layer 200.

The first filler 410 and the second filler 420, in cross-sectional view, are longer than the reflective layer 200. That is, in top view, areas of the first and second fillers 410 and 420 are larger than that of the reflective layer 200, respectively. The areas of the first and second fillers 410 and 410 may be the same as that of the case part 100, respectively.

The solar cell 500 generates electricity using the solar light, and the unit cells 510 are connected to each other through a ribbon 520 in a state of being disposed apart from each other so as to form a dust collecting structure. The solar cell 500 is disposed between the first filler 410 and the second filler 420.

Since the unit cells 510 are disposed apart from each other, the first reflective surface 210 of the reflective layer 200 is exposed between the unit cells 510.

If the transparent plate 110 and the support plate 120 are pressed and heated in a state that the reflective layer 200, the filler layer 400 and the solar cell 500 are sequentially stacked up between the transparent plate 110 and the support plate 120, the filler layer 400 is operated as adhesive and is integrated to the transparent plate 100/the support plate 120.

That is, the first filler 410 completely covers an upper surfaces and side surfaces of the reflective layer 200, and directly contacts with and is fixed to the support plate 120 around the reflective layer 200.

In this manner, the reflective layer 200 containing metal components and the solar cell 500 can be electrically isolated

Further, in order to increase electric insulation between the reflective layer 200 and the solar cell 500, an insulating layer (not shown) being transparent may be formed between the first filler 410 and the reflective layer 200.

In addition, since the first filler 410 is directly coupled to the support plate 120 of glass material according to the present exemplary embodiment, coupling force of the module may be strengthened. If the first filler 410 is attached to the reflective layer 200 and the reflective layer 200 containing the metal components is attached to the support plate 120, durability of the solar cell module may be bad because adherence between the metal components and the glass is bad.

The second filler 420 is directly attached to the transparent plate 110.

The first and second fillers 410 and 420 can be formed as filler layers attached to the transparent plate 110 and the support plate 120 by applying suitable heat and pressure thereto.

Functions and effects of the present exemplary embodiment having the above-mentioned structure will hereinafter be described.

As shown in FIG. 1, the solar light S passing through the transparent plate 110 also passes through the filler layer 400. After that, the solar light S is directly radiated to each unit cell 510 of the solar cell 500 and is used as electricity generation energy.

In addition, the solar light that is not directly radiated to the unit cells 510 and is radiated to the space between the unit cells 510 is radiated to the first reflective surface 220. The solar light that is radiated to the first reflective surface 220 is reflected from the first reflective surface 220 and is supplied to the unit cell 510. The solar light that is reflected from the first reflective surface 220 may be reflected again by the transparent plate 110 and may be then supplied to the unit cell 510.

Since the solar light that is not directly radiated to the unit cells 510 is guided to the unit cells 510 by using the reflective layer 200, electricity generation efficiency of the solar cell may be maximized.

In addition, the solar light S radiated toward the support plate 120 is reflected to the exterior by the second reflective surface 240 of the reflective layer 200 after passing through the support plate 120. Therefore, rise of interior temperature of the solar cell module due to the solar light may be prevented.

According to the present invention, electricity generation efficiency may be enhanced by maximizing collection of the solar light using the reflective layer and cycle-life of the module may be extended by suppressing unnecessary rise of interior temperature.

Variations of the present invention will hereinafter be described.

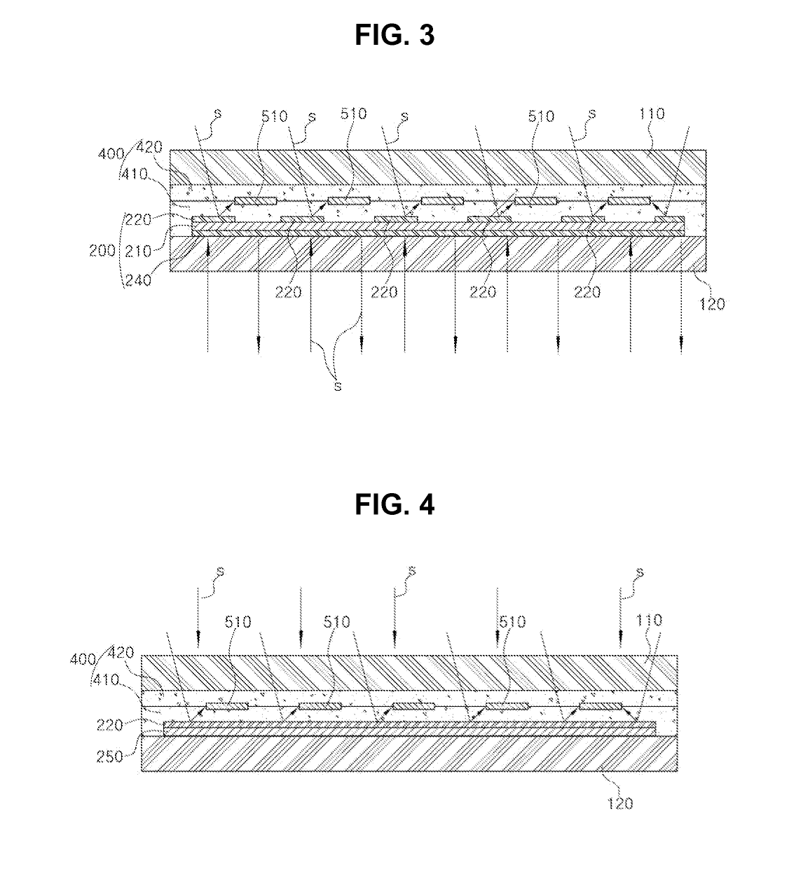

FIG. 3 illustrates another exemplary embodiment of the present invention, and constituent elements of another exemplary embodiment are similar to those of the exemplary embodiment. However, the first reflective surface 220 is not entirely formed on one surface of the body 210 and consists of a plurality of reflective members that are disposed apart from each other such that each reflective member corresponds to a space between a unit cell 510 and a neighboring unit cell 510.

If each of the first reflective surface 220 is formed between neighboring unit cells 510, material used to manufacture the first reflective surface 220 may be reduced.

The present exemplary embodiment may include all of the constitute elements illustrated in FIG. 1 and FIG. 2.

In addition, FIG. 4 illustrates another exemplary embodiment of the present invention, and constituent elements of another exemplary embodiment are substantially the same as those of the exemplary embodiment illustrated in FIG. 1 and FIG. 2. However, the reflective layer 200 is formed with one layer and a thermal insulating member 250 is interposed between the reflective layer 200 and the support plate 120 according to the present exemplary embodiment. In this way, heat transferred through the support plate 120 may be effectively blocked, thereby minimizing rise of interior temperature of the solar cell module.

An insulating layer for increasing insulation with the unit cells 510 may be formed on the reflective layer 200.

The present exemplary embodiment may include all of the constitute elements illustrated in FIG. 1 to FIG. 3.

FIG. 5 illustrates another exemplary embodiment of the present invention, and constituent elements of another exemplary embodiment are substantially the same as those of the exemplary embodiment illustrated in FIG. 1 and FIG. 2. However, structure of the reflective layer 200 is changed so that only the second reflective surface 240 is formed at the body 210.

In this way, rise of interior temperature of the module due to the solar light or geothermy passing through the support plate 120 may be suppressed and manufacturing cost and time of the reflective layer 200 may be reduced.

The present exemplary embodiment may include all of the constitute elements illustrated in FIG. 1 and FIG. 2. If an insulating layer is applied to the present exemplary embodiment, the insulating layer may be opaque because the insulating layer does not need to be transparent.

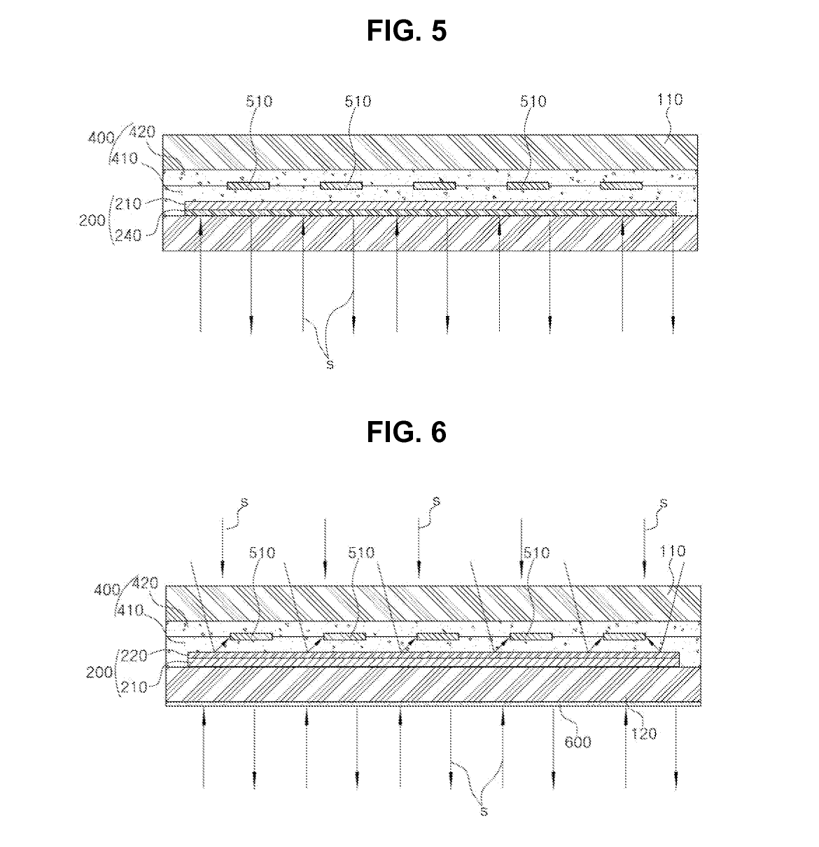

In addition, FIG. 6 illustrates another exemplary embodiment of the present invention, and does not include the second reflective surface 240 like the exemplary embodiment illustrated in FIG. 4. However, the present exemplary embodiment can suppress rise of interior temperature of the module without forming the second reflective surface 240.

For this purpose, the support plate 120 itself is opaque so as to block the solar light or, as shown in the drawing, an additional reflective layer 600 is formed on a surface of the support plate 120 such that the solar light does not pass through the support plate but is reflected by the additional reflective layer 600. Therefore, rise of interior temperature of the module is suppressed.

At this time, the additional reflective layer 600 may formed by white paint or a reflective film and may be sprayed or deposited on the surface of the support plate 120.

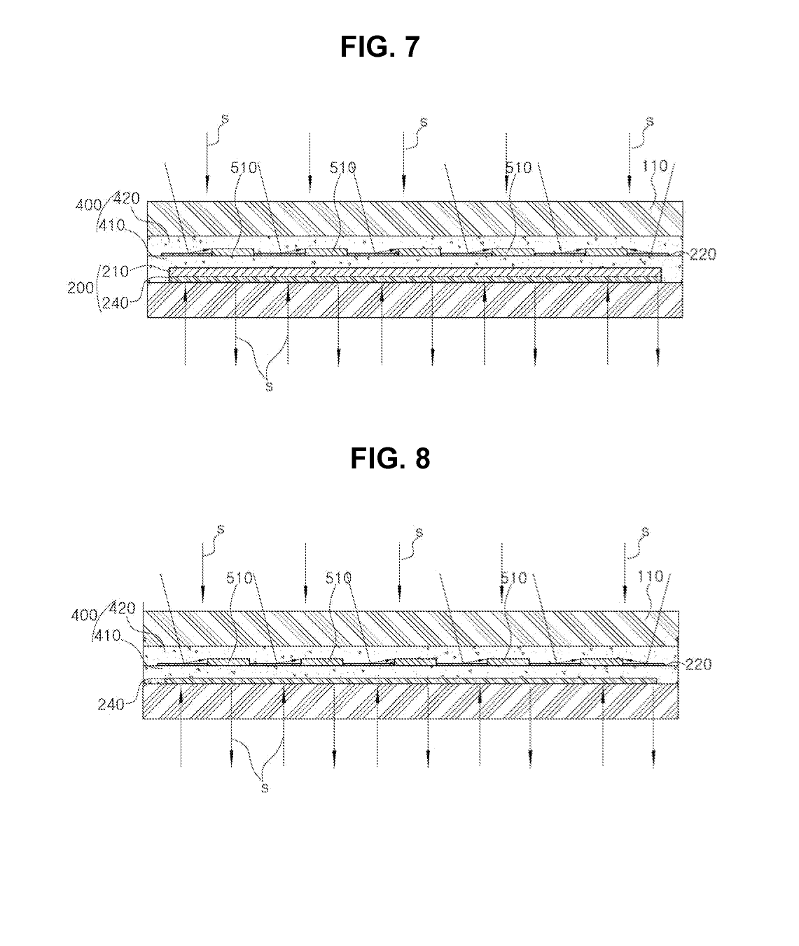

FIG. 7 illustrates another exemplary embodiment of the present invention. According to the present exemplary embodiment, only the second reflective surface 240 is formed at the body 210 like the exemplary embodiment illustrated in FIG. 5 but the filler layer 400 functions as the first reflective surface 220.

For this purpose, the second filler 420 of the filler layer 400 is transparent and the first filler 410 of the filler layer 400 is opaque but can reflect the solar light.

For example, a white resin is used to manufacture the second filler 420 or, as shown in the drawing, the first reflective surface is formed on a part of surfaces of the second filler 420.

Therefore, the solar light passing through the transparent plate 110 and the second filler 420 and radiated between the unit cells 510 is reflected by the first filler 410 and is supplied to each unit cell 510.

If it is less likely to increase interior temperature of the module and the second reflective surface 240 is unnecessary, the body 210 and the second reflective surface 240 are omitted and the second filler 420 is used to reflect the solar light.

In addition, as shown in FIG. 8, the body 210 is omitted and the first and second reflective surfaces 220 and 240 are formed on both surfaces of the first filler 410. In this case, the second filler 420 performs function of the body 210. The first and second reflective surfaces 220 and 240 may be formed on the first filler 410 by white paint or a film that can reflect the solar light.

The present exemplary embodiment may include all of the constitute elements illustrated in FIG. 1 to FIG. 6.

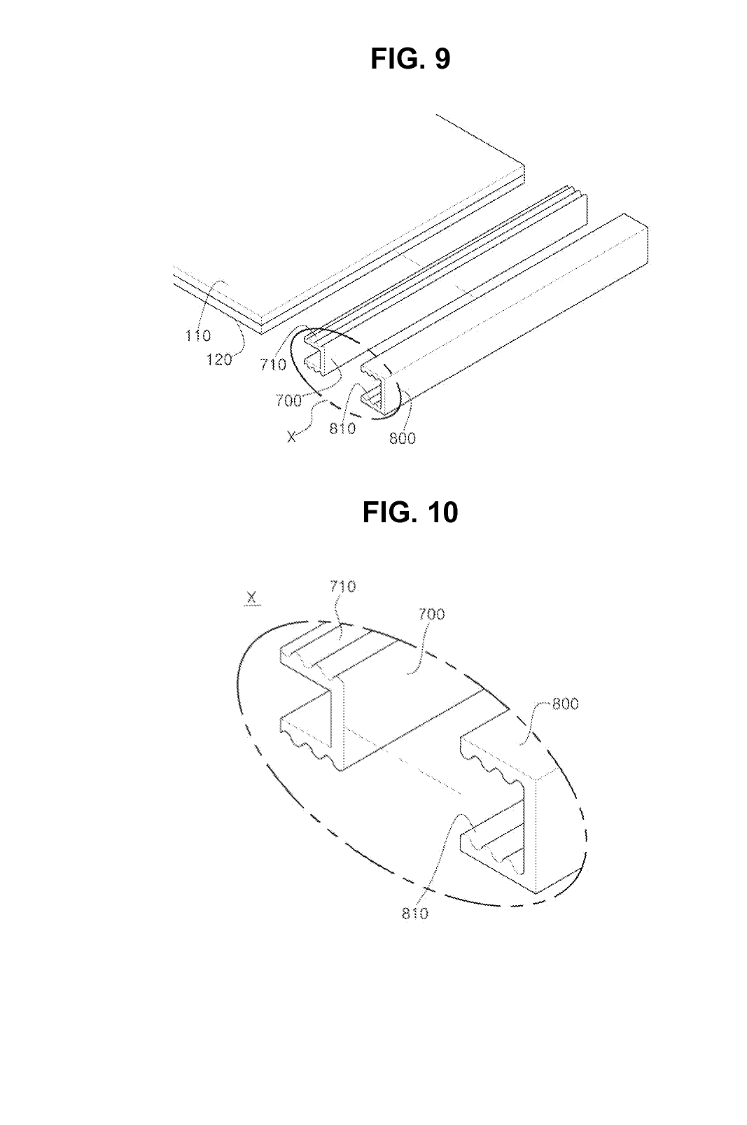

FIG. 9 and FIG. 10 illustrate another exemplary embodiment of the present invention, and constituent elements illustrated in FIG. 1 to FIG. 8 may be applied to the present exemplary embodiment. Addition to such constituent elements, a cover 700 and a frame 800 that cover side surfaces of the transparent plate 110 and the support plate 200 are further included.

The cover 700 may be made of synthetic resin selected from the group consisting of polyamide, polystyrene, acryl, and polyethylene and combinations thereof.

The cover 700 absorbs impact and prevents breakage of the transparent plate 110/the support plate 120 when the frame 800 made of metal is coupled to the transparent plate 110/the support plate 120 made of glass.

The cover 700 are fixed to the side surfaces and peripheries of the transparent plate 110 and the support plate 200 by a silicon (not shown). Protrusions and depressions 710 are formed on an exterior surface of the cover 700.

The frame 800 is made of metal such as aluminum, is fixed to the side surfaces of the transparent plate 110 and the support plate 200, and protects the transparent plate 110 and the support plate 120 made of glass and the unit cells from external impact.

Protrusions and depressions 810 are formed at a surface of the frame 800 contacting with the exterior surface of the cover 700. The protrusions and depressions 810 of the frame 800 is coupled to the protrusions and depressions 710 of the cover 700 such that the frame 800 is fixed to the cover 700.

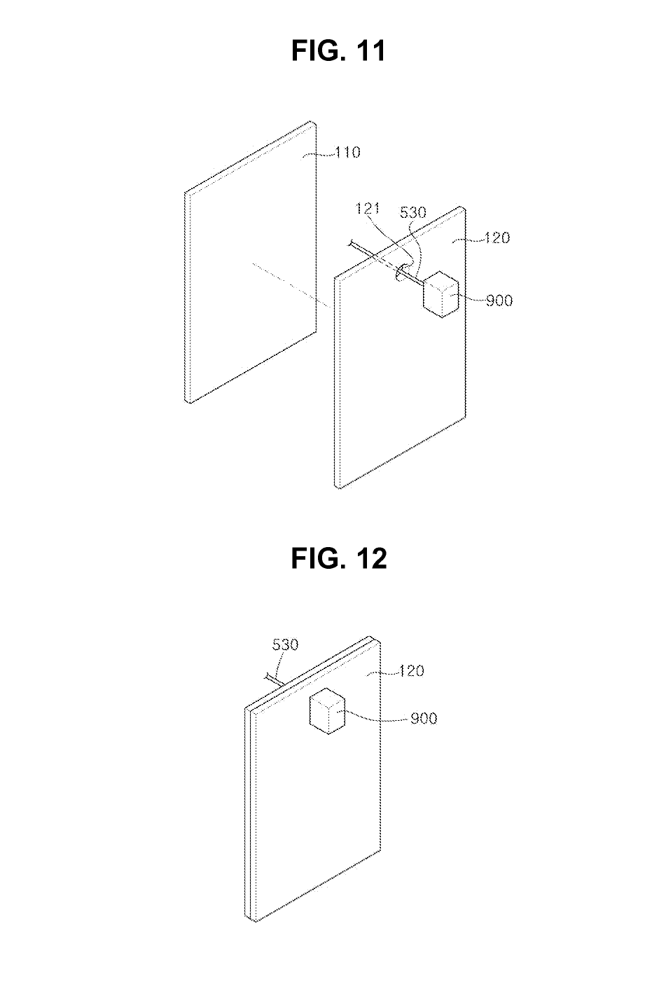

FIG. 11 and FIG. 12 illustrate another exemplary embodiment of the present invention, and constituent elements illustrated in FIG. 1 to FIG. 10 may be applied to the present exemplary embodiment. However, a hole 121 is bored at the support plate 120.

In addition, a junction box 900 is mounted at an exterior surface of the support plate 120. The junction box 900 covers a hole 121.

The ribbons 520 (please refer to FIG. 1) connected to each unit cell 510 are connected to a bus bar 530. The bus bar 530 in the module is drawn out through the hole 121 formed at the support plate 120 and is connected to the junction box 900.

A plurality of bus bars 530 may be provided and a plurality of holes 121 may be formed at the support plate 120. If the plurality of hole 121 are formed at the support plate 120, a plurality of junction boxes 900 are provided such that each junction box 900 covers each hole 121.

In this case, each bus bars 530 may be drawn out through each hole 121. However, some bus bars 530 may be drawn out through one hole 121.

If the bus bar 530 is drawn out between the transparent plate 110 and the support plate 120, that is, through a side of the module, insulation may be damaged by moisture or impact. Since the hole 121 is formed at a position where the junction box 800 is mounted, however, the bus bar 530 can be protected according to the present exemplary embodiment.

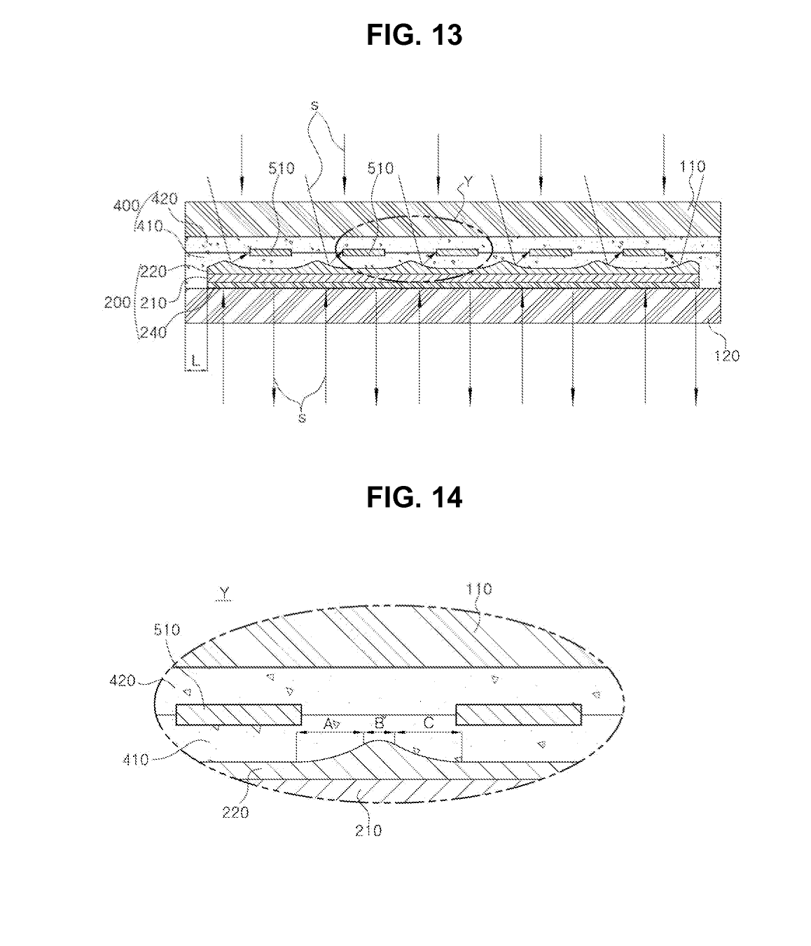

FIG. 13 and FIG. 1410 illustrate another exemplary embodiment of the present invention, and the solar cell module according to the present exemplary embodiment includes the case part 100, the reflective layer 200, the filler layer 400 and the solar cell 500. Constituent elements of the present exemplary embodiment are substantially the same as those of the exemplary embodiments illustrated in FIG. 1 and FIG. 2.

However, a shape of the first reflective surface 220 is changed so as to reflect more solar light to the solar cell 500 according to the present exemplary embodiment.

A part of the first reflective surface 220 may be divided into a first region A, a second region B and a third region C. The first region A and the third region C are convex downwardly, and the second region B is a regions where the first region A and the third region C are joined and is convex upwardly.

However, the second region B may be sharp as a consequence that the first region A and the third region C that are convex downwardly are joined directly at the second region B.

The solar light passing between the unit cells 510 reaches the first region A and the third region C. The solar light reaching the first region A is reflected to the left unit cell 510 in FIG. 14 and the solar light reaching the third region C is reflected to the right unit cell 510 in FIG. 14.

The second region B is convex upwardly so as to minimize force applied to the solar cell 500 when the first reflective surface 220 is attached to the filler layer 400 and the solar cell 500.

When the first reflective surface 220, the filler layer 400 and the solar cell 500 are attached to each other, the sharp second region B may become flat or be convex upwardly. In this case, it is designed that excessive force is not applied to the solar cell 500 even though a sharp portion of the first reflective surface 220 is attached to the filler layer 400 and the solar cell 500.

The present exemplary embodiment may include all of the constitute elements illustrated in FIG. 1 and FIG. 2.

In addition, the first reflective surface 220 including the first, second, and third regions A, B, and C may be applied to the exemplary embodiments illustrated in FIG. 3, FIG. 4, FIG. 6, FIG. 7 and FIG. 8.

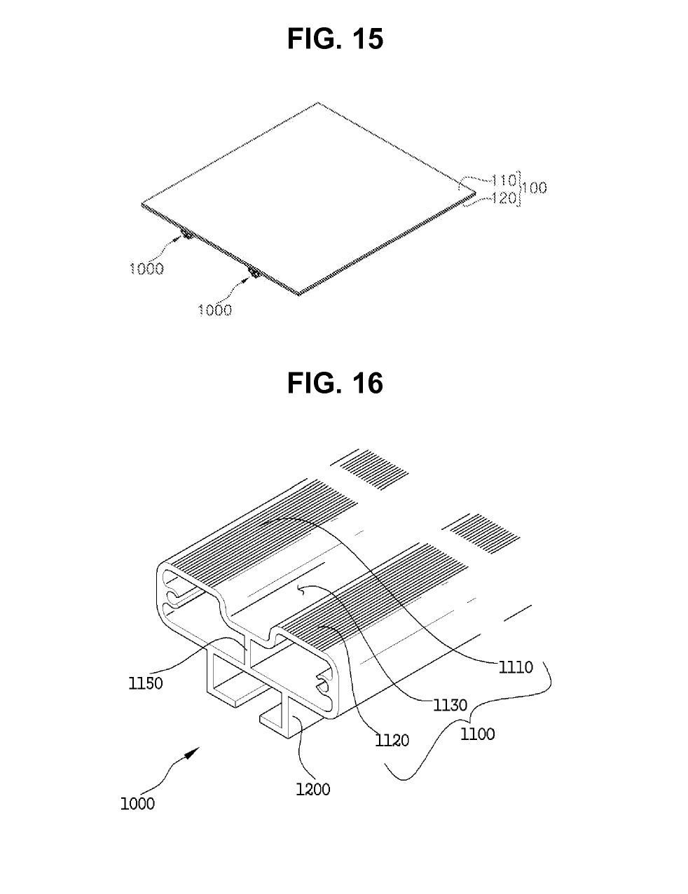

FIG. 15 illustrates a solar cell module according to another exemplary embodiment of the present invention, and FIG. 16 is an enlarged view of the supporter 100 shown in FIG. 15. As shown in FIG. 15 and FIG. 16, the solar cell module according to the present exemplary embodiment includes the case part 100 and a supporter 1000. The case part 100 includes the transparent plate 110 and the support plate 120.

The transparent plate 110 may be made of material such as glass that can passes the solar light. The support plate 120 is mounted to face the transparent plate 110. The reflective layer, the filler layer, and the solar cell are disposed between the transparent plate 110 and the support plate 120. The reflective layer, the filler layer, and the solar cell illustrated in FIG. 1 to FIG. 8, FIG. 11 to FIG. 14 may be applied to the present exemplary embodiment.

However, the present exemplary embodiment may not include the cover 700 and the frame 800 illustrated in FIG. 9 and FIG. 10.

The supporter 1000 is coupled to one surface of the support plate 120. The supporter 1000 may be made of metal or synthetic resin and includes an attaching member 1100 and a coupling member 1200. The supporter 1000 may be coupled to a structure for supporting the solar cell module.

The attaching member 1100 includes first and second regions 1110 and 1120 contacting with the support plate 120 and a third region 1130 positioned between the first region 1110 and the second region 1120 and apart from the support plate 120.

The attaching member 1100 has a hollow space therein and a supporting member 1150 is formed in the hollow space. The supporting member 1150 supports the third region 1130 so as to cause the attaching member 1100 to have predetermined strength. The supporting member 1150 may be omitted.

The first region 1110 and the second region 1120 is attached to the support plate 120 by adhesive such as silicon. Finishing members (not shown) may be coupled to both sides of the attaching member 1100 so as to isolate the hollow space in the attaching member 1100 from the outside.

Since the third region 1130 has a recess shape, a bottom of the third region 1130 is lower than surfaces of the first and second regions 1110 and 1120. Therefore, the third region 1130 can be disposed apart from the support plate 120 by a predetermined gap. The third region 1130 are integrally formed with the first region 1110 and the second region 1120 and connects the first region 1110 and the second region 1120.

According to the present exemplary embodiment, the first region 1110 and the second region 1120 of the supporter 1000 is attached to the support plate 120, and the third portion 1130 between the first region 1110 and the second region 1120 is spaced from the support plate 120. Therefore, even though a bottom surface of the support plate 120 is curved, the first and second regions 1110 and 1120 are moved flexibly along the curvature such that entire surfaces of the first and second regions 1110 and 1120 can closely contact with the support plate. In addition, even though any one region of the first region 1110 or the second region 1120 is detached from the support plate 120 during usage of the solar cell module, the other region of the first region 1110 or the second region 1120 is maintained to be attached to the support plate 120.

If the supporting member 1150 is omitted, the first and second regions 1110 and 1120 can move more flexibly with predetermined resilience. Therefore, even though the bottom surface of the support plate 120 is curved, the first and second regions 1110 and 1120 are moved along the curvature and further closely contact with the support plate.

Since the cover 700 (please see FIG. 9) and the frame 800 (please see FIG. 9) are not mounted in the present exemplary embodiment, a stepped portion is not formed at the transparent plate 110. Since an entire surface of the transparent plate 110 is maintained to be flat, foreign materials such as dust and snow may be easily dropped from the surface of the transparent plate 100. The present exemplary embodiment may be very useful in a desert region where a plenty of gritty dust exist. Since foreign materials are not easily stacked up on the surface of the transparent plate 100, electricity generation efficiency of the solar cell module increases.

In addition, since the cover or the frame are not mounted at the case part 100 according to the present exemplary embodiment, manufacturing process may be simple and weight becomes reduced.

In addition, compared with a conventional solar cell module having the same size, an output may increase. Compared with a conventional solar cell module generating the same output, size may be reduced.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A solar cell module comprising:
a transparent plate,
a support plate positioned to face the transparent plate,
at least one unit cell disposed between the transparent plate and the support plate,
a filler layer formed between the transparent plate and the support plate, and
a reflective layer disposed between the filler layer and the support plate,
wherein a length of the reflective layer is shorter than that of the filler layer, and the filler layer is directly attached with the support plate.

2. The solar cell module of claim 1, wherein the plurality of unit cells are disposed apart from each other, and
wherein the reflective layer includes a plurality of reflective members, the plurality of reflective members are disposed apart from each other, and each reflective member is disposed to face a space between neighboring two of the unit cells.

3. The solar cell module of claim 2, wherein the filler layer pills a space between the plurality of reflective members.

4. The solar cell module of claim 1, further comprising a cover covering sides of the transparent plate and the support plate and made of synthetic resin.

5. The solar cell module of claim 4, wherein the cover is made of resin selected from the group consisting of polyamide, polystyrene, acryl, and polyethylene and combinations thereof.

6. The solar cell module of claim 4, further comprising a metal frame mounted at the cover, wherein protrusions and depressions are formed on contacting surfaces of the cover and the frame, and the cover and the frame are coupled to each other by coupling the protrusions and the depressions with each other.

7. The solar cell module of claim 1, further comprising a junction box mounted at an opposite surface of a surface facing the unit cell among surfaces of the support plate and a bus bar having a side connected to the unit cell and the other side connected to the junction box, wherein a hole is bored at the support plate, the junction box is mounted at a position corresponding to the hole, and the bus bar penetrates through the hole and is connected to the junction box.

8. The solar cell module of claim 1, wherein the at least one unit cell is disposed apart from each other, a surface region of the reflective layer facing the unit cells is flat, and a surface region of the reflective layer facing a space between the neighboring two of the unit cells includes a curved surface being convex upwardly.

9. The solar cell module of claim 1, wherein the reflective layer includes a first reflective surface and a second reflective surface, the first reflective surface reflects light passing through the transparent plate so as to provide the light to the unit cells, and the second reflective surface reflects light passing through the support plate so as to radiate the light to the outside.

10. The solar cell module of claim 1, further comprising an insulating layer formed on the reflective layer and being transparent.

11. The solar cell module of claim 1, wherein the transparent plate and the support plate are made of glass.

12. The solar cell module of claim 1, further comprising a supporter connected to a surface of the support plate opposite to a surface of the support plate facing the reflective layer,
wherein the supporter may include first and second regions attached on the support plate and a third region formed between the first region and the second region and apart from the support plate.

13. A solar cell module comprising:
a transparent plate,
a support plate positioned to face the transparent plate,
at least one unit cell disposed between the transparent plate and the support plate,
a filler layer formed between the transparent plate and the support plate, and
a supporter connected to the support plate,
wherein the supporter includes first and second regions attached on the support plate and a third region formed between the first region and the second region and apart from the support plate.

14. The solar cell module of claim 13, wherein the transparent plate and the support plate are attached by the filler layer, no frame is mounted at edges of the transparent plate and the support plate, and entire outer surfaces of the transparent plate and support plate are flat such that foreign materials can be dropped from the surfaces of the transparent plate and support plate.

15. A method of manufacturing a solar cell module comprising:
disposing a plurality of unit cells between a transparent plate and a support plate,
disposing a first filler between the transparent plate and the unit cell, and disposing a second filler between the support plate and the unit cell,
disposing a reflective layer having plane area smaller than that of the second filler between the second filler and the support plate, wherein solar light is reflected on at least one surface of a surface facing the transparent plate and a surface facing the support plate, and
fixing the plurality of unit cells and directly attaching the second filler and the support plate by heating the first and second fillers.

16-18. (canceled)
